(19) United States
(12) Patent Application Publication
(10) Pub. No.: US 2020/0084906 A1
(43) Pub. Date: Mar. 12, 2020

(54) CHASSIS STRUCTURE FOR FIXING INTERFACE CARD

(71) Applicant: Super Micro Computer Inc., San Jose, CA (US)

(72) Inventors: William SHEN, San Jose, CA (US); Chieh-Tang CHEN, Taoyuan City (TW)

(21) Appl. No.: 16/122,879

(22) Filed: Sep. 6, 2018

(51) Int. Cl. H05K 7/14; H05K 7/16

(52) U.S. Cl. CPC H05K 7/1417; H05K 7/16; H05K 7/1487; H05K 7/1409

(57) ABSTRACT

A case includes a bottom plate, a back plate, and side plates. The side plates have formed positioning pins. A pressing assembly is disposed on the case including a platform and a press plate, and the platform has a bump. A frame includes a dock bracket and a seat bracket. The dock bracket has a positioning hole, and the seat bracket has a through hole. The dock bracket is positioned by the through positioning hole clamping with the positioning pin, and the seat bracket is positioned through rotating the press plate for pressing the through hole and the bump so as to simplify the assembly of a chassis structure for fixing interface cards.

### BACKGROUND OF THE INVENTION

### Field of the Invention

The present invention generally relates to chassis structure and, in particular to chassis structure for fixing interface cards.

### Description of Prior Art

Interface cards are the bridge between the motherboard and peripheral devices. Most traditional server devices are provided with hard disks and print services etc. for network users. In order to let users share resources from network with each other, the server board usually provides multiple interface card slots so as to facilitate the installation of multiple interface cards.

Moreover, an interface card module usually includes an interface card and a frame so that the interface card can be disposed on the frame. In the assembly of the interface card module, the frame is usually fixed by means of screws. However, the assembly with screws is quite time consuming; besides, the screws must be removed from the frame when the interface card is replaced. Therefore, it is quite time consuming and troublesome in operation.

In view of the above drawbacks, the Inventor proposes the present invention based on his expert knowledge and elaborate researches in order to solve the problems of prior art.

### SUMMARY OF THE INVENTION

Accordingly, an object of the present invention is to provide chassis structure for fixing interface cards in which the assembly process can be considerably simplified, and the purpose of shortening working hours can be achieved.

In order to achieve the object mentioned above, the present invention provides chassis structure for fixing interface cards comprising a case, a pressing assembly and a first frame. The case includes a bottom plate, a back plate, and a first side plate and a second side plate located oppositely. The bottom plate, the first side plate and the second side plate are enclosed to form an accommodating space. The back plate encloses a side of the accommodating space. The first side plate has formed a first positioning pin at a side facing the accommodating space. The pressing assembly is disposed on the back plate. The pressing assembly includes a platform and a press plate pivoted on the platform, and the platform has disposed a first bump. The first frame includes a first dock bracket and a first seat bracket being perpendicular and connected to each other. The first dock bracket and the first seat bracket have formed a first installation space for accommodating an interface card. The first dock bracket has formed a first positioning hole corresponding to the first positioning pin. The first seat bracket has a first through hole at a side away from the first dock bracket for clamping the first bump. The first dock bracket is positioned on the first side plate through the first through hole fastening with the first positioning pin, and the first seat bracket is positioned on the back plate through rotating the press plate for pressing the first through hole and the first bump.

Comparing to the prior art, the chassis structure of the present invention has disposed a pressing assembly. After the frame combining with an interface card, one side of the frame (the dock bracket) is positioned on the case by the positioning hole fastening with the positioning pin and the auxiliary positioning pin fixed in the auxiliary positioning hole. Furthermore, the through hole of the seat bracket is clamped on the bump of the pressing assembly. Similarly, another frame can be positioned on the case for combining another interface card. Thereby, frames are fixed on the case without screws. Thus, the assembly of the chassis structure can be simplified for shorting work hours to enhance the practice of the present invention.

### BRIEF DESCRIPTION OF DRAWING

The features of the invention believed to be novel are set forth with particularity in the appended claims. The invention itself, however, may be best understood by reference to the following detailed description of the invention, which describes a number of exemplary embodiments of the invention, taken in conjunction with the accompanying drawings, in which:

FIG. 1 is a perspective schematic view of the chassis structure for fixing interface cards of the present invention;

FIG. 2 is another perspective schematic view of the chassis structure for fixing interface cards of the present invention;

FIG. 3 is a combination schematic view of the first frame and a first interface card of the present invention;

FIG. 4 is a combination schematic view of the second frame and a second interface card of the present invention;

FIG. 5 is a partial perspective view of two interface cards disposed in the case of the present invention;

FIG. 6 is a rotation schematic view of the pressing assembly of the present invention;

FIG. 7 is a pressing schematic view of the pressing assembly of the present invention;

FIG. 8 is a schematic view of the second positioning hole fastened with the second positioning pin of the present invention;

FIG. 9 and FIG. 10 are schematic views of another embodiment of the chassis structure for fixing interface cards of the present invention.

### DETAILED DESCRIPTION OF THE PREFERRED EMBODIMENTS

In cooperation with attached drawings, the technical contents and detailed description of the invention are described thereinafter according to a number of preferable embodiments, being not used to limit its executing scope. Any equivalent variation and modification made according to appended claims is all covered by the claims claimed by the present invention.

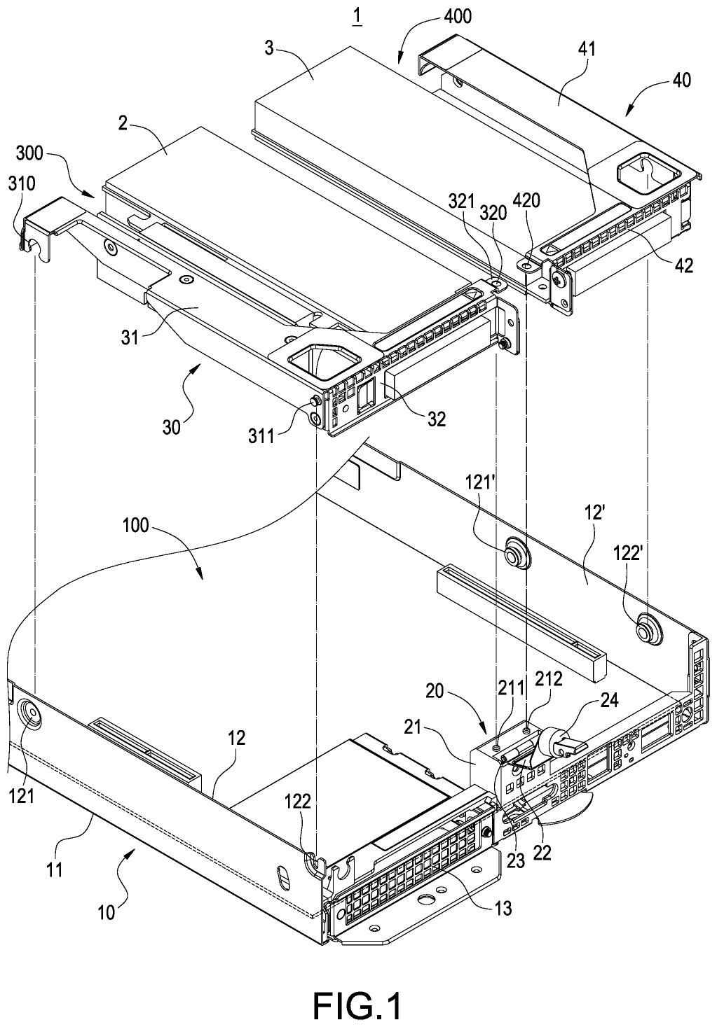

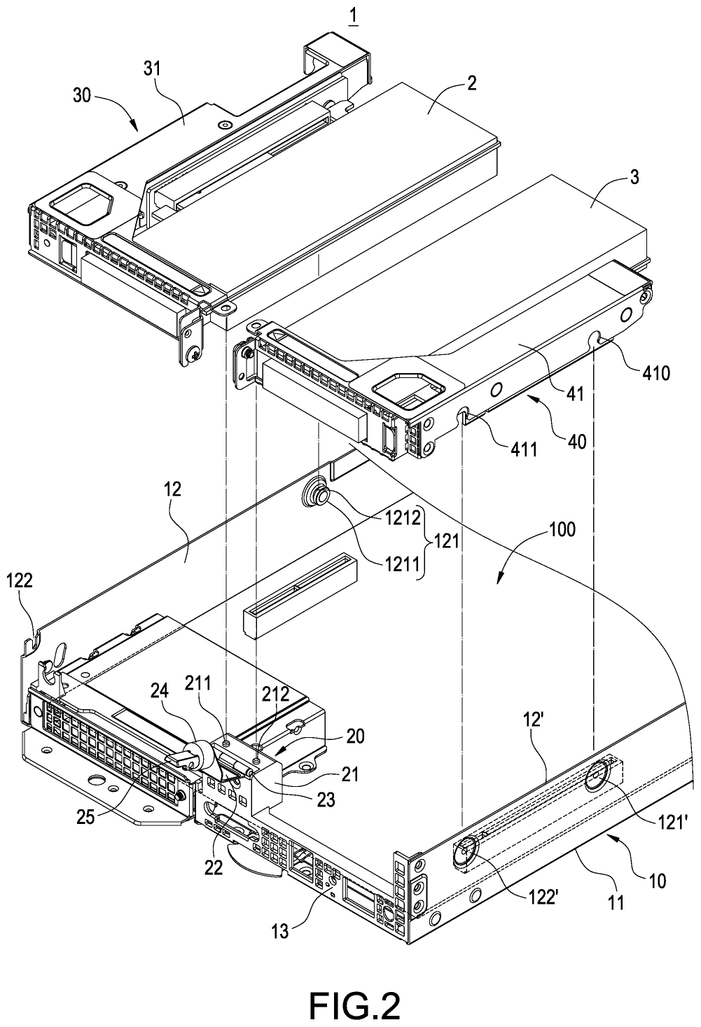

Please refer to FIG. 1 and FIG. 2, which depict two perspective schematic views of the chassis structure for fixing interface cards of the present invention. The chassis structure 1 of the present invention are provided for fixing a first interface card 2. The chassis structure 1 include a case 10, a pressing assembly 20, and a first frame 30. The pressing assembly 20 is combined with the case 10. One side of the first frame 30 is fixed on the case 10 through a fastening method, and the other side is fixed through the pressing assembly 20. In an embodiment of the present invention, the chassis structure 1 further include a second frame 40, and the second frame 40 is provided for fixing a second interface card 3. More detail descriptions of the chassis structure 1 are described as follows.

The case 10 includes a bottom plate 11, a back plate 13, and a first side plate 12 and a second side plate 12′ located oppositely. The bottom plate 11, the first side plate 12 and the second side plate 12′ are enclosed to form an accommodating space 100, and the back plate 13 encloses a side of the accommodating space 100. In addition, the first side plate 12 has formed a first positioning pin 121 at a side facing the accommodating space 100.

The pressing assembly 20 is disposed on the back plate 13, and the pressing assembly 20 includes a platform 21 and a press plate 22 pivoted on the platform 21. The platform 21 has disposed a first bump 211.

The first frame 30 includes a first dock bracket 31 and a first seat bracket 32 being perpendicular and connected to each other. The first dock bracket 31 and the first seat bracket 32 have formed a first installation space 300 for accommodating the first interface card 2. Besides, the first dock bracket 31 has disposed a first positioning hole 310 corresponding to the first positioning pin 121. Furthermore, the first seat bracket 32 has a first through hole 320 at a side away from the first dock bracket 31 for clamping the first bump 211. The first dock bracket 31 is positioned on the first back plate 12 by the first through hole 320 fastening with the first positioning pin 121. Besides, the first seat bracket 32 is positioned on the back plate 13 through rotating the press plate 22 for pressing the first through hole 320 and the first bump 211.

It is worthy of notice that, the present embodiment describes the first interface card 2 fixed by the first truss 30 firstly, and the second interface card 3 fixed by the second frame 40 will be described later.

Please refer to FIG. 1, in the present embodiment, the first positioning hole 310 is located on the first dock bracket 31 at an end away from the first seat bracket 32. The first dock bracket 31 has formed a first auxiliary positioning pin 311 at another end with respect to the first positioning hole 310. Moreover, the first side plate 12 has formed a first auxiliary positioning hole 122 at a side adjacent to the first seat bracket 32, and the first auxiliary positioning pin 311 is fixed in the first auxiliary positioning hole 122. Thereby, the opposite two ends of the first dock bracket 31 are positioned through the first positioning pin 121 and the first auxiliary positioning pin 311 respectively.

In one embodiment of the present invention, the first seat bracket 32 has formed a first lug 321 at a side away from the first dock bracket 31, and the first through hole 320 is located on the first lug 321.

More specifically, the pressing assembly 20 further includes a pivot shaft 23 mounted on the platform 21, and an inner side of the press plate 22 is combined with the pivot shaft 23 and is capable of rotating through the pivot shaft 23. Preferably, the pressing assembly 20 further includes a force button 24, and the force button 24 is disposed at an outer side of the press plate 22 relative to the pivot shaft 23. In an embodiment of the present invention, the pressing assembly 20 further includes a lever 25. The lever 25 is combined with the force button 24 and extended outside the press plate 22 in a direction parallel to the pressure plate 22.

As shown in FIG. 2, specifically, the first positioning pin 121 includes a first stop portion 1211 and a first fastening portion 1212 connected with the first stop portion 1211. The first fastening portion 1212 is connected with the first side plate 12 and fastened with the first positioning hole 310. In addition, the first stop portion 1211 is blocked outside the first positioning hole 310 so that the first dock bracket 31 will not disengage from the first side plate 12. Preferably, the first positioning hole 310 is a U-shaped hole; the first fastening portion 1212 is a conical column, and the diameter of the conical column is gradually increased from the first side plate 12 to the first stop portion 1211.

Furthermore, the manner which the second interface card 3 fixed to the second frame 40 is described as follows. In the present embodiment, the second frame 40 includes a second dock bracket 41 and a second seat bracket 42 which are perpendicular and connected to each other. The second dock bracket 41 and the second seat bracket 42 have formed a second installation space 400 for accommodating the second interface card 3. The second dock bracket 41 has disposed a second positioning hole 410, and the second seat bracket 42 has a second through hole 420 at a side away from the second dock bracket 41.

On the other hand, the second side plate 12′ has formed a second positioning pin 121′ at a side facing the accommodating space 100. The second dock bracket 41 is positioned on the second side plate 12′ through the second positioning hole 410 fastened with the second positioning pin 121′.

Moreover, the platform 21 has a second pump212. The second through hole 420 is clamped on the second bump 212, and the second seat bracket 42 is positioned on the back plate 13 through rotating the press plate 22 and pressing the second through hole 420 and the second pump212. Preferably, the pressing assembly 20 is located between the first seat bracket 32 and the second seat bracket 42.

Specifically, the second positioning hole 410 is located on the second dock bracket 41 at an end away from the second seat bracket 42. The first dock bracket 41 has formed a second auxiliary positioning pin 411 at another end with respect to the second positioning hole 410. The second side plate 12′ has formed a second auxiliary positioning hole 122′ at a side adjacent to the second seat bracket 42, and the second auxiliary positioning pin 122′ is fixed in the second auxiliary positioning hole 411.

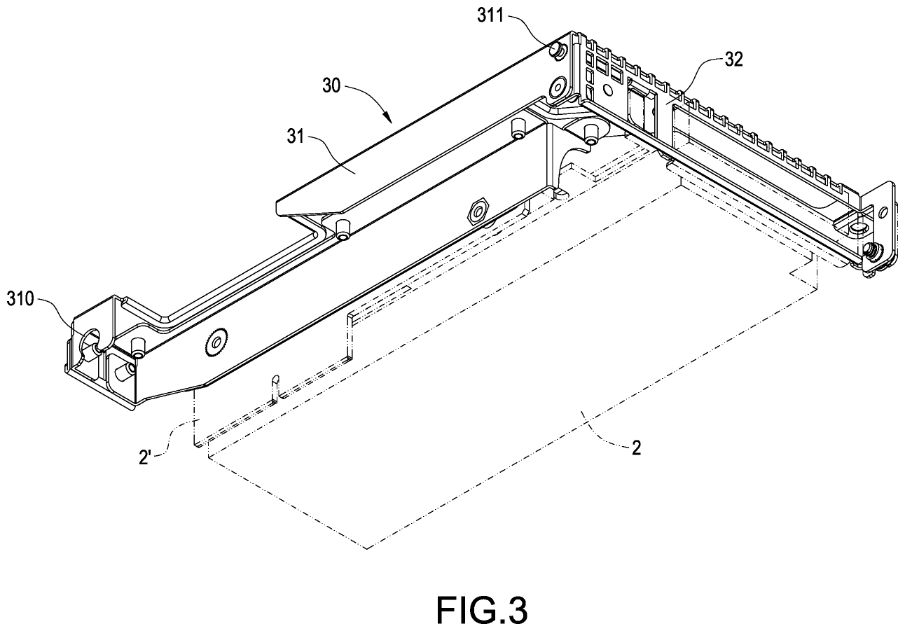

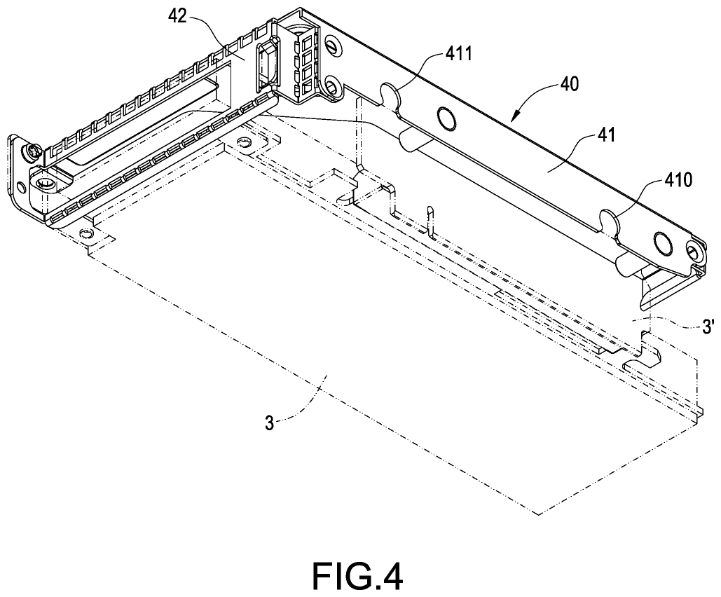

Please also refer to FIG. 3 to FIG. 5. They depict a combination schematic view of the first frame and a first interface card of the present invention, and a combination schematic view of the second frame and a second interface card of the present invention, and a partial perspective view of two interface cards disposed in the case. As shown in FIG. 3, the first interface card 2 is inserted in a first adapter plate 2′. The first adapter plate 2′ is screwed on the first dock bracket 11, thus the first interface card 2 is combined in the first installation space 300. Similarly, as shown in FIG. 4, the second interface card 3 is inserted in a second adapter plate 3′. Also, the second adapter plate 3′ is screwed on the second dock bracket 41; thus, the second interface card 3 will be combined in the second installation space 400.

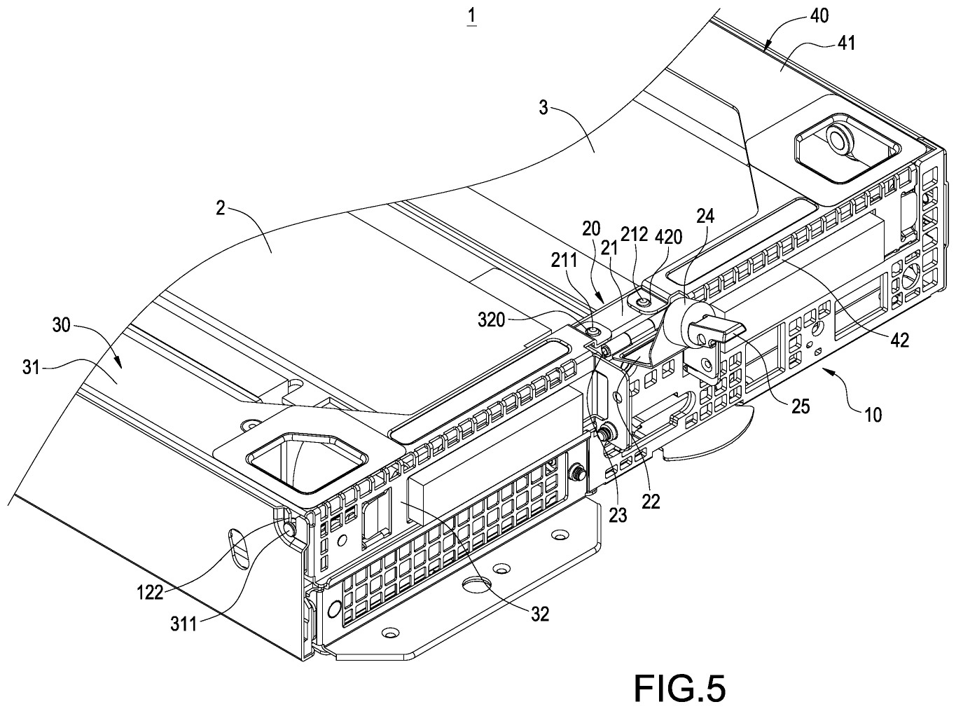

With referring to FIG. 5, after the first frame 30 is combined with the first interface card 2, one side of the first frame 30 (the first dock bracket 31) is positioned on the first side plate 12 by the first positioning hole 310 fastening with the first positioning pin 121 and the first auxiliary positioning pin 311 fixed in the first auxiliary positioning hole 122. In addition, the first through hole 320 of the first seat bracket 32 is clamped on the first bump 211.

Moreover, one side of the second frame 40 (the second dock bracket 41) is positioned on the second side plate 12′ by the second positioning hole 410 fasteing with the second positioning pin 121′ and the second auxiliary positioning pin 122′ fixed in the first auxiliary positioning hole 411. And then, the second through hole 420 of the second seat bracket 42 will be clamped on the second bump 21

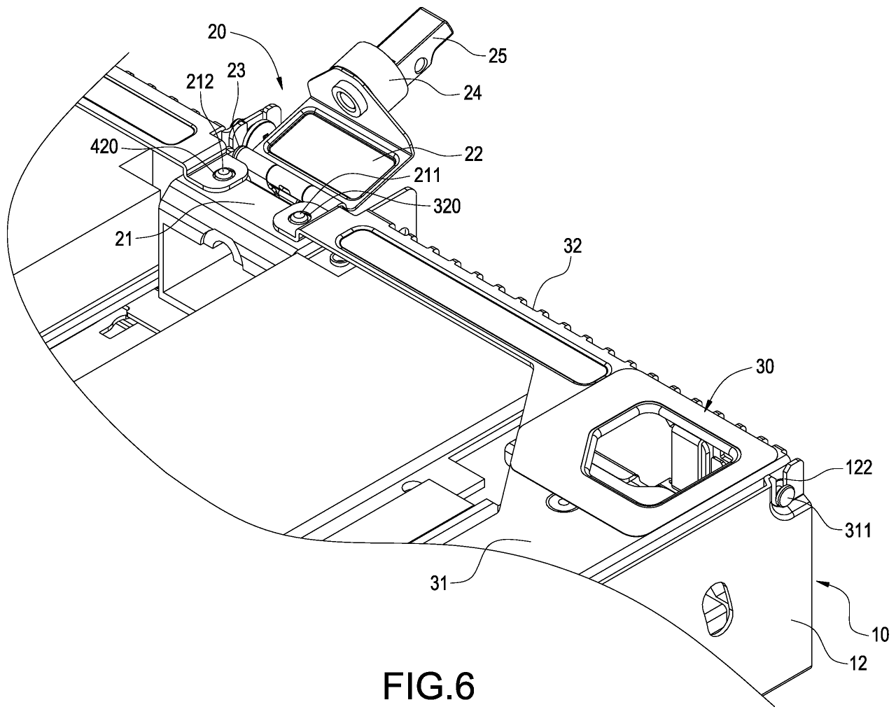

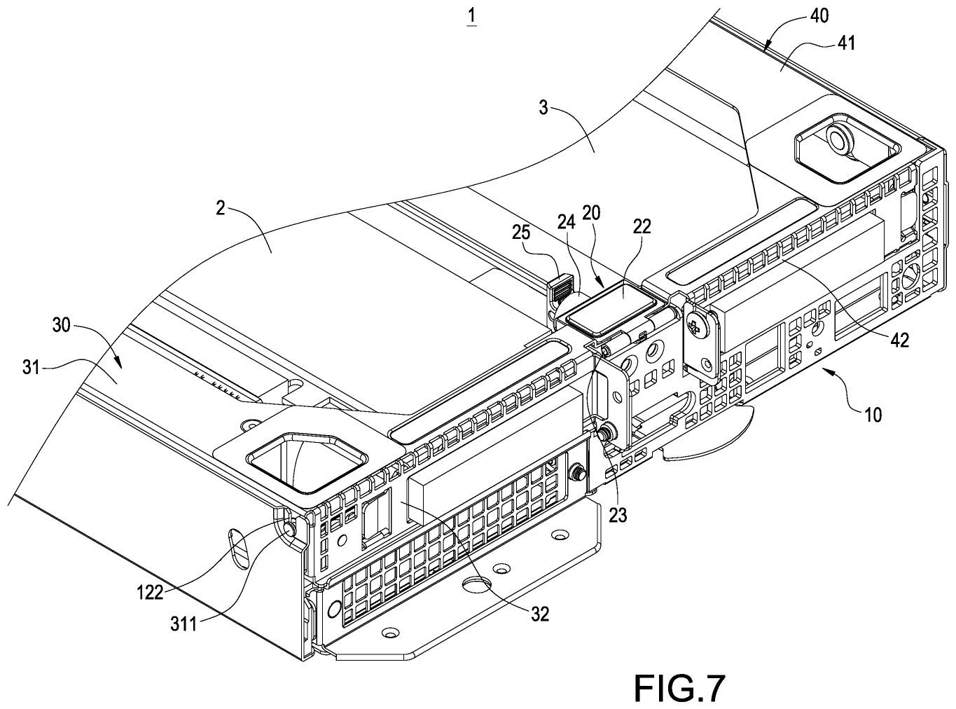

Please refer to FIG. 6 and FIG. 7, they depict a rotation schematic view of the pressing assembly and a pressing schematic view of the pressing assembly of the present invention. After the first frame 30 and the second frame 40 combining in the accommodating space 100, then holding the force button 23 of the pressing assembly 20 and rotating the press plate 22 onto the platform 21 for pressing the first bump 211 and the second bump 211. Accordingly, when a cover (not shown) of the case 10 is combined further for covering the accommodating space 100, the assembly of the first interface card 2 and the second interface card 3 are completed.

It is worthy of notice that, the first frame 30 and the second frame 40 of the present invention are combined to the case 10 without screwing so that the assembly of the first interface card 2 and the second interface card 3 can be simplified, and the purpose of shortening working hours can be achieved.

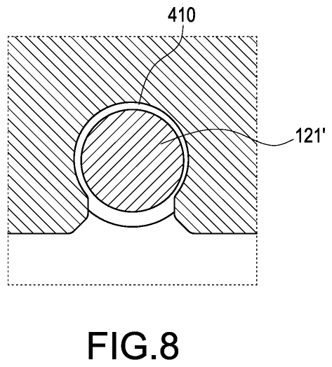

As shown in FIG. 8, it depicts a combination schematic view of second positioning hole and second positioning pin of the present invention. It should be noted that, in this embodiment, the second positioning hole 410 is also a U-shaped hole; the second positioning pin 410 is a conical column, and the diameter of the conical column is gradually increased from the second side plate 12′ for increasing the positioning effect between the second positioning hole 410 and the second positioning pin 121′.

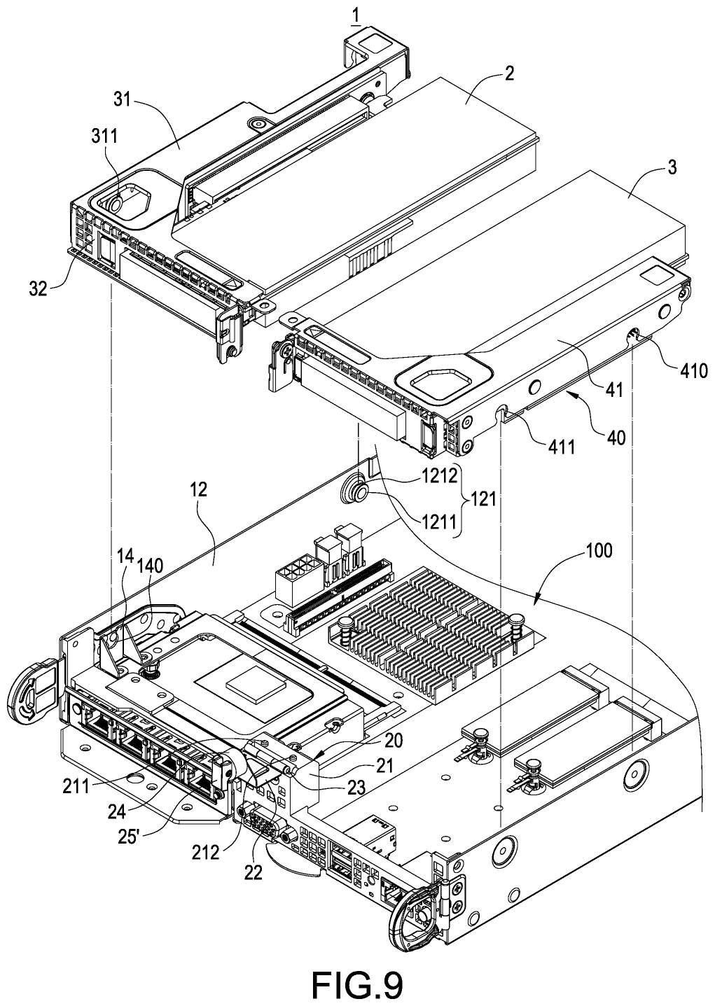

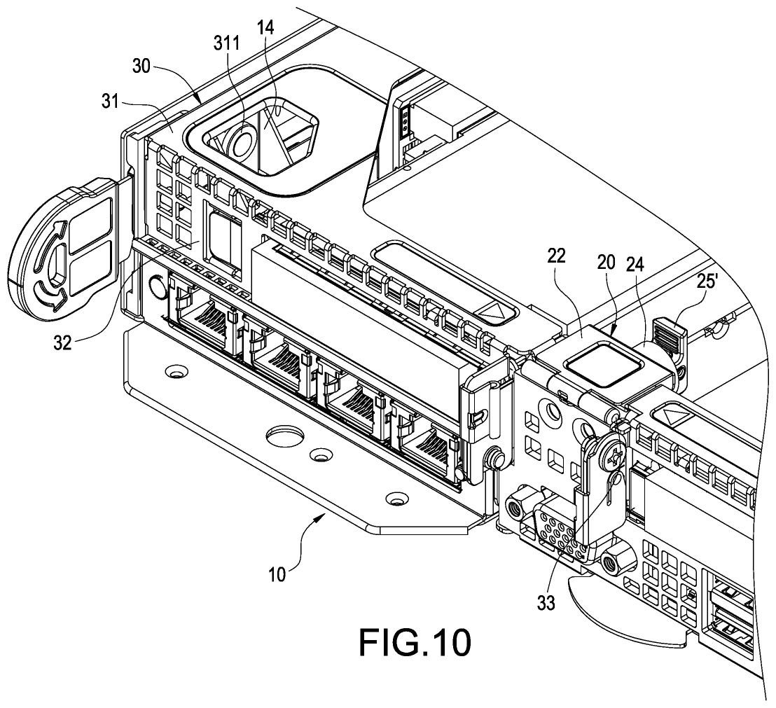

Please refer to FIG. 9 and FIG. 10, they depict another embodiment of the chassis structure for fixing interface cards of the present invention. This embodiment is substantially the same as the previous embodiment, and differs in the design of the force button. In the present embodiment, the pressing assembly 20 further includes a lever 25′. The lever 25′ is combined with the force button 24 and extended in a direction perpendicular to the press plate 22.

Furthermore, another difference of this embodiment is the fixed position of the first auxiliary positioning pin 311. In the present embodiment, the first side plate 12 has formed an upright plate 14 at a side adjacent to the first seat bracket 32, and the upright plate 14 has formed a first auxiliary positioning hole 140, and the first auxiliary positioning pin 311 is fixed in the first auxiliary positioning hole 140. Moreover, the method of fixing interface cards is substantially the same as the pervious and details are not described herein again.

Although the present invention has been described with reference to the preferred embodiment thereof, it will be understood that the invention is not limited to the details thereof. Various substitutions and improvements have been suggested in the foregoing description, and others will occur to those of ordinary skill in the art. Therefore, all such substitutions and improvements are intended to be embraced within the scope of the invention as defined in the appended claims.

What is claimed is:

1. A chassis structure for fixing interface card, comprising:
a case including a bottom plate, a back plate, and a first side plate and a second side plate located oppositely; the bottom plate, the first side plate and the second side plate enclosing an accommodating space; the back plate enclosing a side of the accommodating space, and the first side plate having a first positioning pin at a side facing the accommodating space;
a pressing assembly disposed on the back plate; the pressing assembly including a platform and a press plate pivoted on the platform, and the platform having a first bump; and
a first frame including a first dock bracket and a first seat bracket being perpendicular and connected to each other; the first dock bracket and the first seat bracket formed a first installation space for accommodating an interface card; the first dock bracket having a first positioning hole corresponding to the first positioning pin, and the first seat bracket having a first through hole for clamping the first bump at a side away from the first dock bracket; the first dock bracket positioned on the first back plate by the first through hole fastening with the first positioning pin, and the first seat bracket positioned on the back plate through rotating the press plate for pressing the first through hole and the first bump.

2. The chassis structure for fixing interface card according to claim 1, wherein the first positioning pin includes a first stop portion and a first fastening portion connected with the first stop portion; the first fastening portion is connected with the first side plate and fastened with the first positioning hole, and the first stop portion is blocked outside the first positioning hole so that the first dock bracket will not disengage from the first side plate.

3. The chassis structure for fixing interface card according to claim 2, wherein the first positioning hole is a U-shaped hole; the first fastening portion is a conical column, and a diameter of the conical column is gradually increased from the first side plate to the first stop portion.

4. The chassis structure for fixing interface card according to claim 1, wherein the first positioning hole is located on the first dock bracket at an end away from the first seat bracket; the first dock bracket has formed a first auxiliary positioning pin at another end with respect to the first positioning hole; the first side plate has formed a first auxiliary positioning hole at a side adjacent to the first seat bracket, and the first auxiliary positioning pin is fixed in the first auxiliary positioning hole.

5. The chassis structure for fixing interface card according to claim 1, wherein the first seat bracket has formed a first lug at a side away from the first dock bracket, and the first through hole is located on the first lug.

6. The chassis structure for fixing interface card according to claim 1, wherein the pressing assembly further includes a pivot shaft mounted on the platform; an inner side of the press plate is combined with the pivot shaft and is capable of rotating through the pivot shaft.

7. The chassis structure for fixing interface card according to claim 6, wherein the pressing assembly further includes a force button, the force button is disposed at an outer side of the press plate relative to the pivot shaft.

8. The chassis structure for fixing interface card according to claim 1, further including a second frame, wherein the second frame includes a second dock bracket and a second seat bracket which are perpendicular and connected to each other; the second dock bracket and the second seat bracket are formed a second installation space for accommodating an interface card; the second dock bracket has a second positioning hole, and the second seat bracket has a second through at a side away from the second dock bracket.

9. The chassis structure for fixing interface card according to claim 8, wherein the second side plate has formed a second positioning pin at a side facing the accommodating space; the second dock bracket is positioned on the second side plate through the second positioning hole clamping with the second positioning pin.

10. The chassis structure for fixing interface card according to claim 9, wherein the platform has a second pump; the second through hole is fastened on the second bump, and the second seat bracket is positioned on the back plate through rotating the press plate for pressing the second through hole and the second bump.

11. The chassis structure for fixing interface card according to claim 10, wherein the second positioning hole is located on the second dock bracket at an end away from the second seat bracket, and the second dock has formed a second auxiliary positioning hole at another end with respect to the second positioning hole; the second side plate has formed a second auxiliary positioning pin at a side adjacent to the second seat bracket, and the second auxiliary positioning pin is fixed in the second auxiliary positioning hole.

12. The chassis structure for fixing interface card according to claim 10, wherein the pressing assembly is located between the first seat bracket and the second seat bracket.

13. The chassis structure for fixing interface card according to claim 1, wherein the first positioning pin is located on the first dock bracket at an end away from the first seat bracket, and the first dock bracket has formed a first auxiliary positioning pin at another end with respect to the first positioning hole; the first side plate has formed an upright plate at a side adjacent to the first seat bracket, and the upright plate has formed a first auxiliary positioning hole; the first auxiliary positioning pin is fixed in the first auxiliary positioning hole.

14. The chassis structure for fixing interface card according to claim 7, wherein the pressing assembly further includes a lever; the lever is combined with the force button and extended outside the press plate in a direction parallel to the pressure plate.

15. The chassis structure for fixing interface card according to claim 7, wherein the pressing assembly further includes a lever; the lever is combined with the force button and extended in a direction perpendicular to the press plate.
